(19) United States
(12) Patent Application Publication
(10) Pub. No.: US 2013/0056858 A1
(43) Pub. Date: Mar. 7, 2013

(54) INTEGRATED CIRCUIT AND METHOD FOR FABRICATING THE SAME

(71) Applicants: Tian-You DING, Hsinchu City (TW); Meng-Jia LIN, Changhua County (TW); Chin-Sheng YANG, Hsinchu City (TW)

(72) Inventors: Tian-You DING, Hsinchu City (TW); Meng-Jia LIN, Changhua County (TW); Chin-Sheng YANG, Hsinchu City (TW)

(73) Assignee: UNITED MICROELECTRONICS CORPORATION, HSINCHU (TW)

(21) Appl. No.: 13/223,375

(22) Filed: Sep. 1, 2011

(51) Int. Cl. H01L 21/3065; H01L 29/06

(52) U.S. Cl. 257/622; 438/712; 257/415; 257/E21.218; 257/E29.022

(57) ABSTRACT

A method for fabricating integrated circuit is provided. First, a substrate having a micro electromechanical system (MEMS) region is provided. A first interconnect structure and a hard mask layer have been disposed on the MEMS region in sequence. Next, an anisotropic etching process is performed by using the hard mask layer as a photo mask to etch a portion of the first interconnect structure exposed by the hard mask layer. Accordingly, a MEMS structure is formed. A portion of the substrate in MEMS region is exposed by the MEMS structure. Then, an isotropic etching process is performed for removing the portion of the substrate in MEMS region to form a cavity with a center region and a ring-like indentation region. The center region is surrounded by the ring-like indentation region and the MEMS structure suspends above the cavity. An integrated circuit is also provided.

### BACKGROUND

1. Technical Field

The present invention generally relates to a method for fabricating an integrated circuit and more particularly to an integrated circuit with a MEMS structure and a method for fabricating the same.

2. Description of the Related Art

Micro electromechanical system (MEMS) technique has established a whole new technical field and industry. The MEMS technique has been widely used in a variety of microelectronic devices that have electronic and mechanical properties, for example, pressure sensors, accelerators and micro-microphones.

Furthermore, complementary metal oxide semiconductor (CMOS) process is usually used to fabricate the MEMS for decreasing the cost and integrating the process of the MEMES and the driving circuit thereof. Therefore, how to create or improve the process integrating CMOS and MEMS is an important issue for the MEMS industry.

### BRIEF SUMMARY

Accordingly, the invention is directed to a method for fabricating an integrated circuit, which can etch the substrate with different depths during an etching process.

The invention is also directed to an integrated circuit including a MEMS structure, and there are different distances between the MEMS structure and the substrate.

The invention provides a method for fabricating integrated circuit including the following steps. First, a substrate having a micro electromechanical system (MEMS) region is provided. A first interconnect structure and a hard mask layer have been disposed on the MEMS region in sequence. Next, an anisotropic etching process is performed by using the hard mask layer as a photo mask to etch a portion of the first interconnect structure exposed by the hard mask layer. Accordingly, a MEMS structure is formed. A portion of the substrate in MEMS region is exposed by the MEMS structure. Then, an isotropic etching process is performed for removing the portion of the substrate in MEMS region to form a cavity with a center region and a ring-like indentation region. The center region is surrounded by the ring-like indentation region and the MEMS structure suspends above the cavity. An integrated circuit is also provided.

In an embodiment of the invention, the anisotropic etching process is, for example, reactive ion etching (RIE) process.

In an embodiment of the invention, the method further includes the step of using terafluoromethane (CF₄) and octafluorocyclobutane (C₄F₈) as etching gases.

In an embodiment of the invention, a ratio of flow rate between CF₄ and C₄F₈ equals 4.

In an embodiment of the invention, the method further includes the step of using trifluoromethane (CHF₃) or hexafluoroethane (C₂F₆) as etching gases.

In an embodiment of the invention, a process temperature of the anisotropic etching process is larger than 60 degrees centigrade.

In an embodiment of the invention, a process pressure of the anisotropic etching process is between 50 mT and 500 mT.

In an embodiment of the invention, a process power of the anisotropic etching process is between 300 W and 3000 W.

In an embodiment of the invention, the method further includes the step of using an F-containing gas as etching gas during the isotropic etching process.

In an embodiment of the invention, the F-containing gas includes sulfur hexafluoride (SF₆), nitrogen trifluoride (NF₃) or CF₄.

In an embodiment of the invention, the method further includes the step of using helium gas or nitrogen gas as a dilute gas during the isotropic etching process.

In an embodiment of the invention, a process temperature of the isotropic etching process is between −15 degrees centigrade and 5 degrees centigrade.

In an embodiment of the invention, the first interconnect structure includes a plurality of first dielectric layers and a plurality of first conductive patterns stacked therewith alternately on the MEMS region, the hard mask layer is disposed on the top layer of the first dielectric layers and corresponds to the first conductive patterns so that exposes a portion of the top layer of the first dielectric layers. The anisotropic etching process is used for removing a portion of the first dielectric layers.

In an embodiment of the invention, the method further includes the step of removing the hard mask layer after removing the portion of the first interconnect structure exposed by the hard mask layer.

In an embodiment of the invention, the method further includes the step of removing the hard mask layer during the anisotropic etching process.

In an embodiment of the invention, the substrate further has a logic circuit region and a second interconnect structure has been formed thereon, the second interconnect structure includes a plurality of second dielectric layers, a plurality of second conductive patterns and at least a pad. The second dielectric layers and the second conductive patterns stacked with each other alternately on the MEMS region. The pad disposed on the second conductive patterns. The top layer of the second dielectric layers has at least an opening exposing the pad. The method further includes the steps of forming a patterned photoresist layer on the second interconnect structure before performing the anisotropic etching process and removing the patterned photoresist layer after performing the anisotropic etching process.

The invention is also provided an integrated circuit including a substrate and a MEMS structure. The substrate has a MEMS region with a cavity having a ring-like indentation region and a center region surrounded thereby. The MEMS structure partially disposed above the cavity.

In an embodiment of the invention, the depth ratio of the ring-like indentation region and a center region is between 1.5 and 3.5.

In an embodiment of the invention, the integrated circuit further includes a second interconnect structure and the substrate further has a logic circuit region where the second interconnect structure disposed on. The second interconnect structure includes a plurality of second dielectric layers, a plurality of second conductive patterns and at least a pad. The second dielectric layers and the second conductive patterns stacked with each other alternately on the MEMS region. The pad disposed on the second conductive patterns. The top layer of the second dielectric layers has at least an opening exposing the pad.

During the fabricating process of integrated circuit of the invention, a portion of the substrate beyond the MEMS structure is etched to form a cavity having a ring-like indentation region and a center region with different depths. Therefore, the MEMS structure partially suspending above the cavity can has flexible space of vibration.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1A through FIG. 1D are schematic cross-sectional views illustrating parts of fabricating process steps of an integrated circuit in accordance with an embodiment of the present invention; and

FIG. 2 is a schematic view illustrating a portion of the substrate.

### DETAILED DESCRIPTION

The integrated circuit of the invention is fabricated by CMOS process. A MEMS integrated to a CMOS circuit would be described as examples in the following embodiments, but the invention is not limited hereto. The invention also can be applied in a MEMS structure without CMOS circuit.

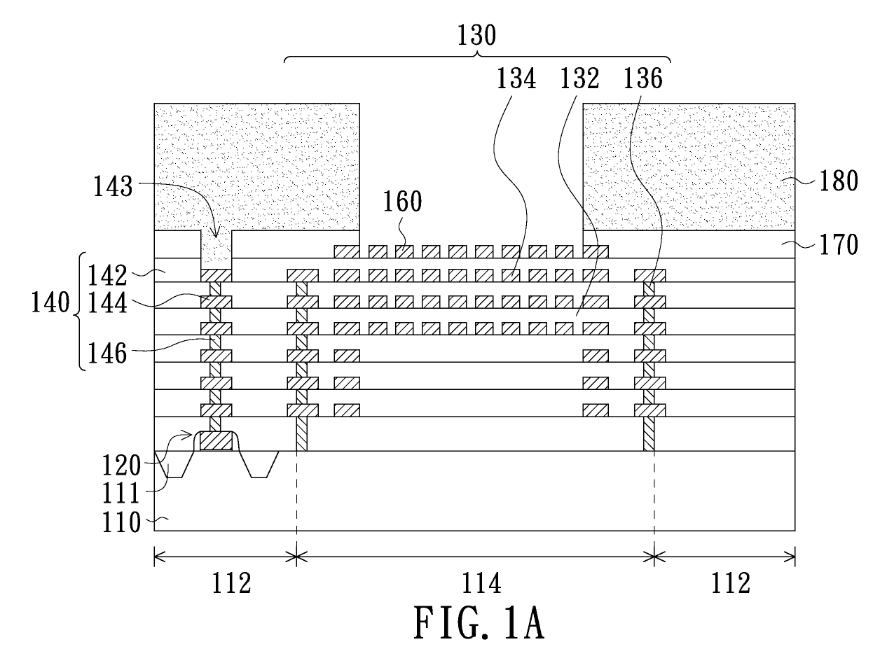

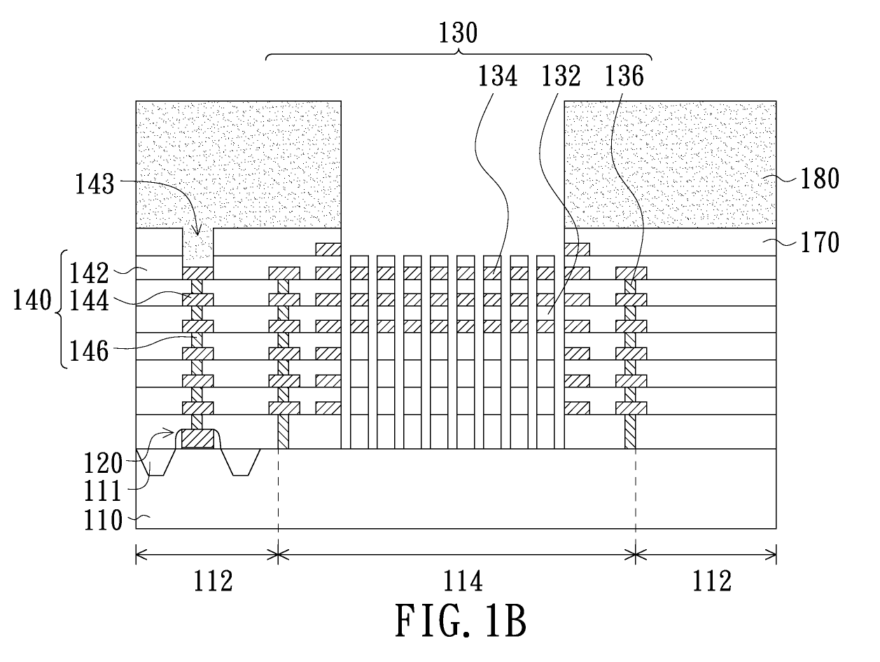

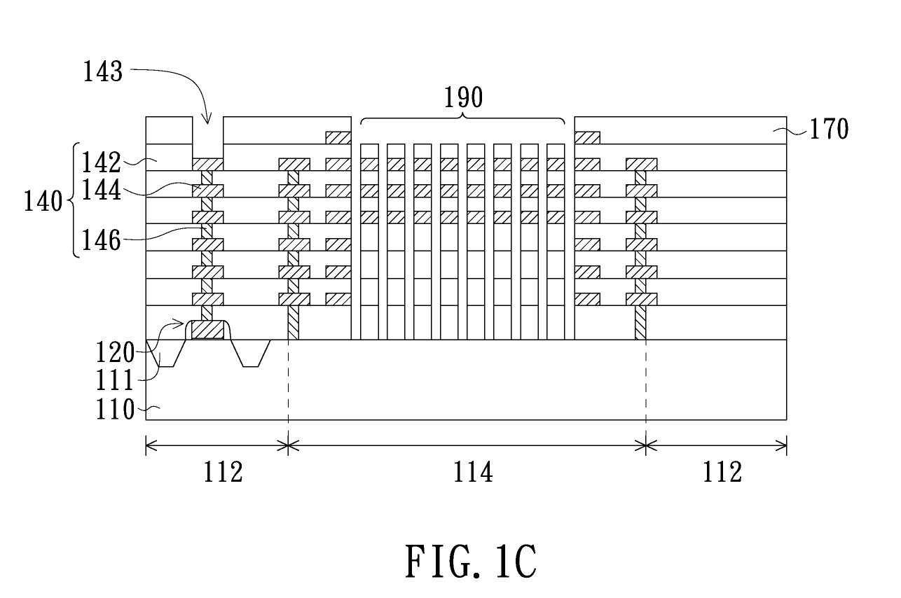

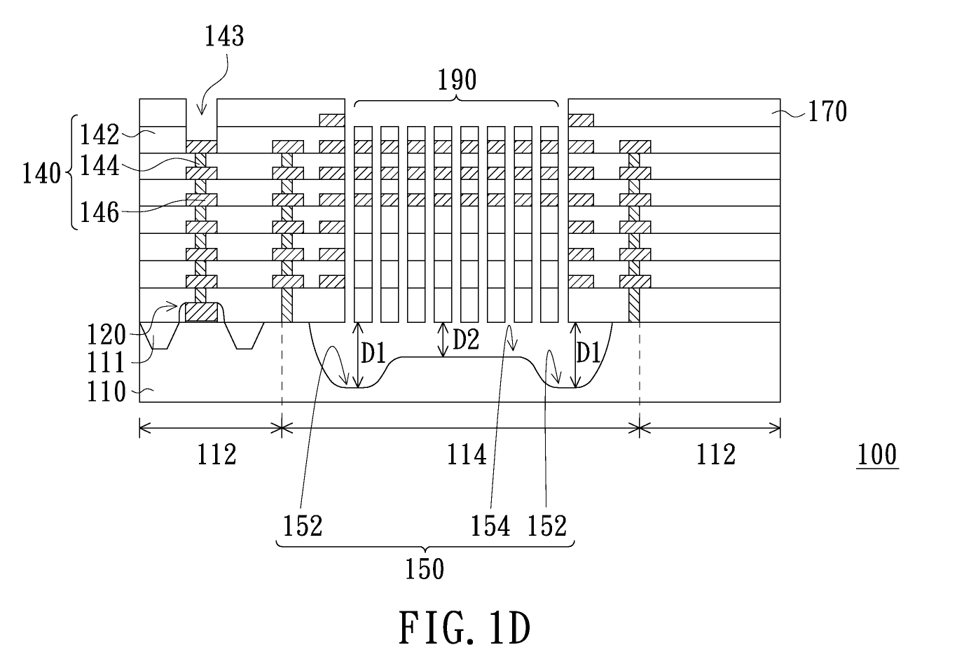

FIG. 1A through FIG. 1D are schematic cross-sectional views illustrating parts of fabricating process steps of an integrated circuit in accordance with an embodiment of the present invention. Referring to FIG. 1A, a substrate 110 has a logical circuit region 112 and a MEMS region 114 is provided. In this embodiment, the substrate may be silicon substrate or silicon on insulator substrate. Moreover, at least a semiconductor device 120 has been formed on the logical circuit region 202. In this embodiment, the semiconductor device 120 is, for example, complementary metal oxide semiconductor (so-called CMOS). Specifically, if there is a plurality of semiconductor devices 120 formed in the logic circuit region 112, the semiconductor devices 120 would be separated from each other by the shallow trench isolations 111.

A first interconnect structure 130 including a plurality of first dielectric layers 132, a plurality of first conductive patterns 134 and a plurality of contact vias 136 is formed on the MEMS region 114 of the substrate 110. Simultaneously, a second interconnect structure 140 including a plurality of second dielectric layers 142, a plurality of second conductive patterns 144 and a plurality of contact vias 146 is formed on the logic circuit region 112 of the substrate 110. The first conductive patterns 134 are stacked and interlaced with the first dielectric layers 132 and the conductive patterns 134 formed in two adjacent layers are electrically connected to each other by the contact vias 136 formed in the first dielectric layer 132. The materials of the first dielectric layer 132 and the second dielectric layer 142 is, for example, oxide. Further, at least a portion of the conductive patterns 144 is electrically connected to the semiconductor device 120 through the contact vias 146.

Next, a hard mask layer 160 is formed on the first interconnect structure 130. The hard mask layer 160 corresponds to the first conductive patterns 134 and a portion of the interlayer 150 is exposed by the hard mask layer 160. In specific, the material of the hard mask layer may be metal nitride, such as titanium nitride.

In this embodiment, a protective layer 170 is formed on the first interconnect structure 130 and the second interconnect structure 140 for covering the hard mask layer 160. The protective layer 170 may be a single layer or multi-layers composed of, for example, an oxide layer and a nitride layer stacked thereon.

Next, the portion of the protective layer 170 above the MEMS region 114 and the top layer of the second dielectric layer 142 may be removed to form an opening 143 to expose the highest second conductive patterns 144. The exposing highest second conductive patterns 144 are used to be contact pads and the semiconductor device 120 can electrically connect with external circuit for electricity test through the contact pads.

Then, the portion of the protective layer 170 above the MEMS region 114 is removed to expose the hard mask layer 160. In specific, a patterned photoresist layer 180 is formed on the protective layer 170 for defining the portion of the protective layer 170 is going to be removed. After that, the portion of the protective layer 170 is removed by using the patterned photoresist layer 180 as a mask for exposing the hard mask layer 160.

Referring to FIGS. 1A and 1B, an anisotropic etching process is performed and the hard mask layer 160 is used as a mask for removing the portion of the first dielectric layer 132 exposed by the hard mask layer 160 above the MEMS region 114 to expose a portion of the substrate 110. Therefore, a MEMS structure 190 is formed above the MEMS region 114. Then, referring to FIG. 1C, the patterned photoresist layer 180 is removed.

In this embodiment, the first dielectric layers 132 are removed by performing, for example, reactive ion etching (RIE) process. Furthermore, terafluoromethane (CF₄) and octafluorocyclobutane (C₄F₈) are used as etching gases during the process, and ratio of the flow rate between CF₄ and C₄F₈ is, for example, 4. Of course, in other embodiments of the invention, trifluoromethane (CHF₃) or hexafluoroethane (C₂F₆) may also be used as etching gases, but the invention is not limited hereto. Moreover, the process temperature of the anisotropic etching process is larger than 60 degrees centigrade, the process pressure of the anisotropic etching process is about 50 mT to 500 mT and the process power of the anisotropic etching process is about 300 W to 3000 W. In a preferably embodiment, process pressure and the process power of the anisotropic etching process are respectively 174 mT and 1750 W.

It should be known that the first interconnect structure 130 includes the plurality of first dielectric layers 132, that is, the thickness of the first dielectric layers 130 being removed is larger than the thickness of the hard mask layer 160 in this step. Accordingly, the hard mask layer 160 may be removed during the anisotropic etching process.

Referring to FIG. 1D, an isotropic etching process is performed for removing a portion of the substrate 110 in the MEMS region 114 to form a cavity under the MEMS structure 190. Accordingly, a portion of the MEMS structure 190 suspends above the substrate 110. At this time, the fabricating process of an integrated circuit 100 including semiconductor elements and MEMS elements is accomplished. In specific, the portion of the MEMS structure 190 of this embodiment suspending above the substrate 110 may be cantilevers to compose an accelerators, but it is not limited hereto.

In this embodiment, the F-containing gases are used in the isotropic etching process for etching the substrate 110. For example, the F-containing gases may include sulfur hexafluoride (SF₆) and nitride gas or helium gas may be dilute gas in the isotropic etching process. In other embodiments, nitrogen trifluoride (NF₃) or CF₄ may also be the etching gases used in the isotropic etching process, but it is not limited hereto. In this embodiment, the process temperature of the isotropic etching process is about −15 to 5 degrees centigrade, the process pressure of the isotropic etching process is about 200 mT and the process power of the isotropic etching process is, for example, is higher than 5000 W.

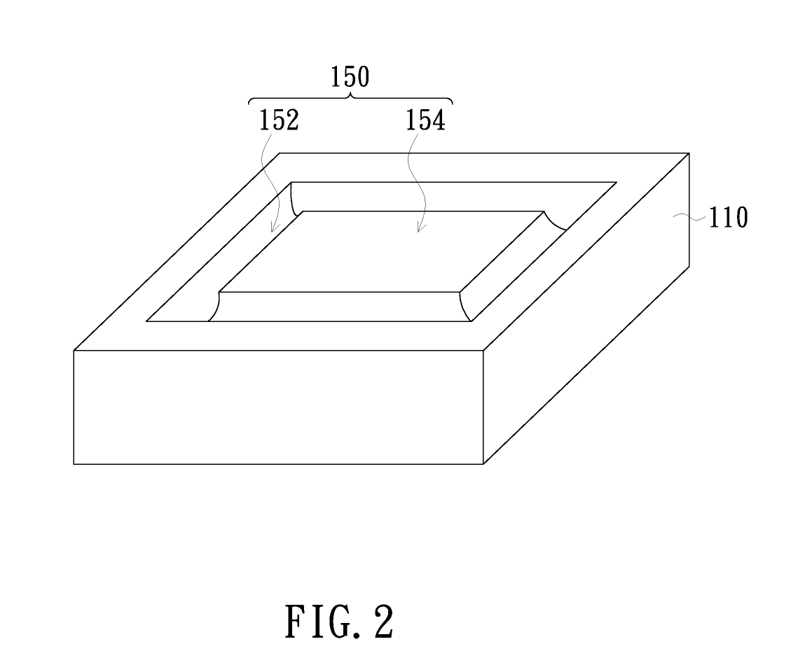

Especially, after removing the portion of the substrate 110 by the isotropic etching process, a cavity 150 having a ring-like indentation region 152 and a center region 154 is formed. As shown in FIG. 2, the center region 154 is surrounded by the ring-like indentation region 152.

The integrated circuit fabricated by the aforementioned method would be expanded in the following embodiment.

Referring to FIG. 1D again, the integrated circuit 100 includes a substrate 110 and a MEMS structure 190. The substrate 110 has a MEMS region 114 with a cavity 150. The cavity 150 has a ring-like indentation region 152 and a center region 154. The center region 154 is surrounded by the ring-like indentation region 152. The MEMS structure 190 partially suspends above the cavity 150. In specific, the ratio between the depth D1 of the ring-like indentation region 152 and the depth D2 of the center region 154 is, for example, 1.5 to 3.5. In this embodiment, the depth D1 of the ring-like indentation region 152 is, for example between 71.7 micrometer and 76.1 micrometer, and the depth D2 of the center region 154 is about 29.8 micrometer.

Furthermore, the integrated circuit 100 also includes a semiconductor device 120 and a second interconnect structure 140 disposed on the logic circuit region 114 of the substrate 110. The second interconnect structure 140 including a plurality of second dielectric layers 142, a plurality of second conductive patterns 144 and a plurality of contact vias 146 is formed on the logic circuit region 112 of the substrate 110. The second conductive patterns 144 are stacked and interlaced with the second dielectric layers 142 and the second conductive patterns 144 formed in two adjacent layers are electrically connected to each other by the contact vias 146 formed in the first dielectric layer 132. Further, the MEMS structure 190 is electrically connected to the semiconductor device 120 through the second interconnect structure 140 for controlling the MEMS structure 190 by the semiconductor device 120.

In summary, during the fabricating process of integrated circuit of the invention, a portion of the substrate beyond the MEMS structure is etched to form a cavity having a ring-like indentation region and a center region with different depths. Therefore, the MEMS structure partially suspending above the cavity can has flexible space of vibration.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

1. A method for fabricating an integrated circuit, comprising:
providing a substrate with a MEMS region, wherein a first interconnect structure and a hard mask layer disposed on the MEMS region in sequence;
performing an anisotropic etching process by using the hard mask layer as a mask to remove a portion of the first interconnect structure exposed by the hard mask layer for forming a MEMS structure, wherein a portion of the substrate in the MEMES region is exposed by the MEMS structure; and
performing an isotropic etching process to remove the portion of the substrate in the MEMS region for forming a cavity having a ring-like indentation region and a center region surrounded thereby, the MEMS structure suspends above the cavity.

2. The method as claimed in claim 1, wherein the anisotropic etching process comprises reactive ion etching process.

3. The method as claimed in claim 2, further comprises the step of using terafluoromethane (CF₄) and octafluorocyclobutane (C₄F₈) as etching gases.

4. The method as claimed in claim 3, wherein a ratio of flow rate between CF₄ and C₄F₈ equals 4.

5. The method as claimed in claim 2, further comprises the step of using trifluoromethane (CHF₃) or hexafluoroethane (C₂F₆) as etching gases.

6. The method as claimed in claim 1, wherein a process temperature of the anisotropic etching process is larger than 60 degrees centigrade.

7. The method as claimed in claim 1, wherein a process pressure of the anisotropic etching process is between 50 mT and 500 mT.

8. The method as claimed in claim 1, wherein a process power of the anisotropic etching process is between 300 W and 3000 W.

9. The method as claimed in claim 1, further comprises the step of using an F-containing gas as etching gas during the isotropic etching process.

10. The method as claimed in claim 9, wherein the F-containing gas comprises sulfur hexafluoride (SF₆), nitrogen trifluoride (NF₃) or CF₄.

11. The method as claimed in claim 9, further comprises the step of using helium gas or nitrogen gas as a dilute gas in the isotropic etching process.

12. The method as claimed in claim 1, wherein a process temperature of the isotropic etching process is between −15 degrees centigrade and 5 degrees centigrade.

13. The method as claimed in claim 1, wherein the first interconnect structure comprises a plurality of first dielectric layers and a plurality of first conductive patterns stacked therewith alternately on the MEMS region, the hard mask layer disposed on the top layer of the first dielectric layers and corresponds to the first conductive patterns so that exposes a portion of the top layer of the first dielectric layers, the anisotropic etching process is used for removing a portion of the first dielectric layers.

14. The method as claimed in claim 1, further comprises the step of removing the hard mask layer after removing the portion of the first interconnect structure exposed by the hard mask layer.

15. The method as claimed in claim 1, further comprises the step of removing the hard mask layer during the anisotropic etching process.

16. The method as claimed in claim 1, wherein the substrate further has a logic circuit region and a second interconnect structure has been formed thereon, the second interconnect structure comprises a plurality of second dielectric layers, a plurality of second conductive patterns and at least a pad, the second dielectric layers and the second conductive patterns stacked with each other alternately on the MEMS region, the pad disposed on the second conductive patterns, the top layer of the second dielectric layers has at least an opening exposing the pad, the method further comprises the steps of forming a patterned photoresist layer on the second interconnect structure before performing the anisotropic etching process and removing the patterned photoresist layer after performing the anisotropic etching process.

17. An integrated circuit, comprising:
a substrate has a MEMS region with a cavity having a ring-like indentation region and a center region surrounded thereby; and
a MEMS structure partially disposed above the cavity.

18. The integrated circuit as claimed in claim 17, wherein the depth ratio of the ring-like indentation region and a center region is between 1.5 and 3.5.

19. The integrated circuit as claimed in claim 17, further comprises a second interconnect structure and the substrate further has a logic circuit region, the second interconnect structure disposed on the logic circuit region and comprises a plurality of second dielectric layers, a plurality of second conductive patterns and at least a pad, the second dielectric layers and the second conductive patterns stacked with each other alternately on the MEMS region, the pad disposed on the second conductive patterns, the top layer of the second dielectric layers has at least an opening exposing the pad.
